(19) United States
(12) Patent Application Publication
(10) Pub. No.: US 2017/0243777 A1
(43) Pub. Date: Aug. 24, 2017

(54) PLASMA PROCESSING APPARATUS AND METHOD OF MANUFACTURING SEMICONDUCTOR DEVICE

(71) Applicant: KABUSHIKI KAISHA TOSHIBA, Minato-ku (JP)

(72) Inventors: Takashi OHASHI, Yokkaichi (JP); Atsushi KUBOTA, Kuwana (JP)

(73) Assignee: KABUSHIKI KAISHA TOSHIBA, Minato-ku (JP)

(21) Appl. No.: 15/248,719

(22) Filed: Aug. 26, 2016

(30) Foreign Application Priority Data
Feb. 22, 2016 (JP) 2016-031242

(51) Int. Cl. H01L 21/683; H01L 21/3065; H01J 37/32

(52) U.S. Cl. CPC H01L 21/6831; H01J 37/32009; H01J 37/32449; H01J 37/32724; H01L 21/3065

(57) ABSTRACT

In one embodiment, a plasma processing apparatus includes an electrostatic chuck configured to hold a substrate. The apparatus further includes a surrounding member holder configured to hold a surrounding member that surrounds an edge portion of the substrate. The apparatus further includes a plasma feeder configured to feed plasma for processing the substrate to a side of a first face of the substrate. The apparatus further includes a gas feeder configured to feed a gas to a space between the edge portion of the substrate and the surrounding member by discharging the gas to a side of a second face of the substrate from a gas hole provided on a side face of the electrostatic chuck or a gas hole provided in the surrounding member.

### CROSS REFERENCE TO RELATED APPLICATION

This application is based upon and claims the benefit of priority from the prior Japanese Patent Application No. 2016-31242, filed on Feb. 22, 2016, the entire contents of which are incorporated herein by reference.

### FIELD

Embodiments described herein relate to a plasma processing apparatus and a method of manufacturing a semiconductor device.

### BACKGROUND

In recent years, structures of flash memories have been transiting from two-dimensional structures to three-dimensional structures. As a result, it is necessary to form deeper holes on a front face (first face) of a wafer by plasma etching, which takes long time. This etching causes a problem that a rear face (second face) of the wafer is etched by plasma to the extent that is not negligible. For example, if the plasma etching of the rear face of the wafer proceeds, a hole may be formed in a protection film due to wet etching that is performed after the plasma etching. In this case, a film to be protected is etched during the wet etching. The same problem may occur in other plasma processing that processes the front face of the wafer (substrate) by plasma.

### BRIEF DESCRIPTION OF THE DRAWINGS

FIG. 1 is a cross-sectional view illustrating a structure of a plasma processing apparatus in a first embodiment;

FIG. 2 is a cross-sectional view schematically illustrating a structure of an ESC in the first embodiment;

FIG. 3 is a cross-sectional view illustrating a structure of a plasma processing apparatus in a comparative example of the first embodiment;

FIG. 4 is a cross-sectional view illustrating a structure of a plasma processing apparatus in a second embodiment;

FIG. 5 is a cross-sectional view illustrating a structure of a semiconductor device in a third embodiment; and

FIG. 6A to 10B are cross-sectional views illustrating a method of manufacturing the semiconductor device in the third embodiment.

### DETAILED DESCRIPTION

Embodiments will now be explained with reference to the accompanying drawings.

In one embodiment, a plasma processing apparatus includes an electrostatic chuck configured to hold a substrate. The apparatus further includes a surrounding member holder configured to hold a surrounding member that surrounds an edge portion of the substrate. The apparatus further includes a plasma feeder configured to feed plasma for processing the substrate to a side of a first face of the substrate. The apparatus further includes a gas feeder configured to feed a gas to a space between the edge portion of the substrate and the surrounding member by discharging the gas to a side of a second face of the substrate from a gas hole provided on a side face of the electrostatic chuck or a gas hole provided in the surrounding member.

### First Embodiment

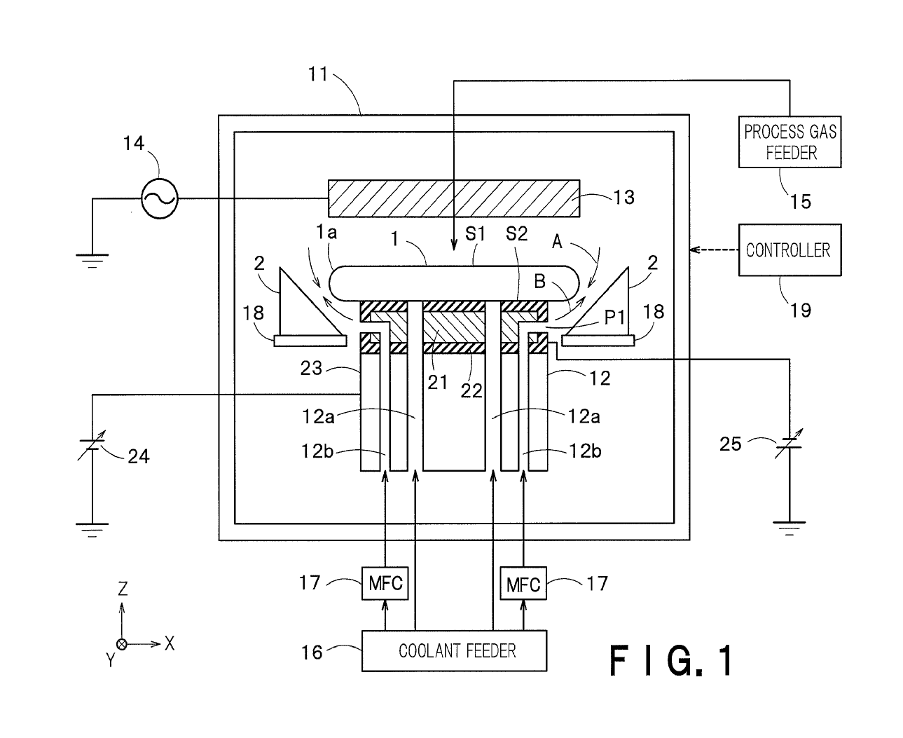

FIG. 1 is a cross-sectional view illustrating a structure of a plasma processing apparatus in a first embodiment. For example, the plasma processing apparatus in FIG. 1 is a plasma etching device.

FIG. 1 illustrates a wafer 1 and a dummy ring 2 in the plasma processing apparatus. The wafer 1 is an example of a substrate. The dummy ring 2 is an example of a surrounding member.

The plasma processing apparatus in FIG. 1 includes a process chamber 11, an electrostatic chuck (ESC) 12, an upper electrode 13, an AC power supply 14, a process gas feeder 15, a coolant feeder 16, mass flow controllers (MFCs) 17, a dummy ring holder 18 and a controller 19. The ESC 12, the upper electrode 13, the AC power supply 14 and the process gas feeder 15 are an example of a plasma feeder. The coolant feeder 16 is an example of a gas feeder. The MFCs 17 are an example of a flow rate controller. The dummy ring holder 18 is an example of a surrounding member holder. The ESC 12 includes a high voltage (HV) electrode (lower electrode) 21, an insulator 22, an ESC base 23, an HV power supply 24 and an ESC power supply 25. The upper electrode 13 is an example of a first electrode. The HV electrode 21 is an example of a second electrode.

The process chamber 11 houses the wafer 1 to be processed. FIG. 1 shows X and Y directions that are parallel with a front face S1 and a rear face S2 of the wafer 1 and are perpendicular to each other, and a Z direction that is perpendicular to the front face S1 and the rear face S2 of the wafer 1. The front face (upper face) S1 of the wafer 1 is an example of a first face. The rear face (lower face) S2 of the wafer 1 is an example of a second face. A bevel (edge portion) 1a of the wafer 1 is positioned at a boundary between the front face S1 and the rear face S2 of the wafer 1. In the present specification, the +Z direction is regarded as an upward direction, and the −Z direction is regarded as a downward direction. The −Z direction in the present embodiment may coincide with the gravity direction or may not coincide with the gravity direction.

The ESC 12 holds the wafer 1 in the process chamber 11. The upper electrode 13 is provided outside the ESC 12 while the HV electrode 21 is provided in the ESC 12. The HV electrode 21 is covered with the insulator 22, and is provided on the ESC base 23. The HV power supply 24 is a variable voltage source for adjusting the potential of the HV electrode 21. The ESC power supply 25 is a variable voltage source for adjusting the potential of the ESC base 23. The wafer 1 is placed on the HV electrode 21 via the insulator 22. The ESC 12 attracts the wafer 1 electrostatically by the HV electrode 21. The ESC 12 includes an upper face on which the wafer 1 is placed, a lower face that is opposed to the upper face, and a side face provided with gas holes P1. The ESC 12 can move the wafer 1 upwardly and downwardly with pins provided on the upper face of the ESC 12.

The upper electrode 13 is provided above the HV electrode 21. The plasma processing apparatus generates plasma between the upper electrode 13 and the HV electrode 21, feeds the plasma to the side of the front face S1 of the wafer 1, and processes the wafer 1 by the plasma. Specifically, the front face S1 of the wafer 1 is etched by dry etching using the plasma. As indicated by an arrow A, radicals in the plasma reach a space between the bevel 1a of the wafer 1 and the dummy ring 2.

The AC power supply 14 supplies an AC current to the upper electrode 13. The plasma is thereby generated between the upper electrode 13 and the HV electrode 21.

The process gas feeder 15 supplies a process gas for generating the plasma in the process chamber 11. The upper electrode 13 and the HV electrode 21 generate the plasma from the process gas with the AC current from the AC power supply 14. An example of the process gas is a silicon tetrachloride (SiF₄) gas.

The coolant feeder 16 feeds a coolant to the wafer 1 via first flow paths 12a that are provided in the ESC 12. The coolant in the present embodiment is an inert gas such as a rare gas, for example, a helium (He) gas. The coolant feeder 16 further feeds the He gas to second flow paths 12b that are connected to the gas holes P1. The He gas is discharged from the gas holes P1 to the side of the rear face S2 of the wafer 1. As a result, as illustrated by an arrow B, the He gas is fed to the space between the bevel 1a of the wafer 1 and the dummy ring 2 so that the space is filled with the He gas.

Each MFC 17 corresponds to a pair of a second flow path 12b and a gas hole P1. Each MFC 17 feeds the He gas from the coolant feeder 16 to the corresponding second flow path 12b, and controls the flow rate of the He gas discharged from the corresponding gas hole P1.

The dummy ring holder 18 holds the dummy ring 2 such that the dummy ring 2 surrounds the bevel 1a of the wafer 1. The dummy ring 2 and the dummy ring holder 18 have ring shapes. The dummy ring 2 is arranged in order to prevent excessive plasma from reaching the bevel 1a to excessively etch the bevel 1a.

The controller 19 controls the operation of the plasma processing apparatus. For example, the controller 19 controls the operation of the process chamber 11, the operation of the ESC 12, on-and-off and a current of the AC power supply 14, on-and-off and a feeding amount of the process gas of the process gas feeder 15, on-and-off and a feeding amount of the coolant of the coolant feeder 16, the control of the flow rate by the MFCs 17 and the like.

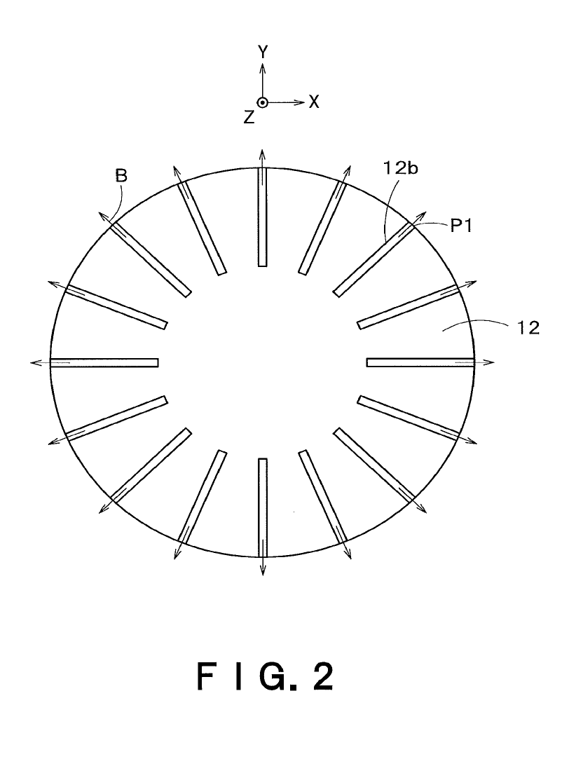

FIG. 2 is a cross-sectional view schematically illustrating a structure of the ESC 12 in the first embodiment.

FIG. 2 illustrates an X-Y section of the ESC 12 taken at the height of the gas holes P1. As illustrated in FIG. 2, the second flow paths 12b in the ESC 12 extend radially in the vicinities of the gas holes P1. The second flow paths 12b are arranged at equal intervals in FIG. 2, but may be arranged at non-equal intervals. Furthermore, each second flow path 12b may have a shape other than the radial shape in the vicinity of the corresponding gas hole P1.

Comparison between the first embodiment and a comparative example will be proposed below.

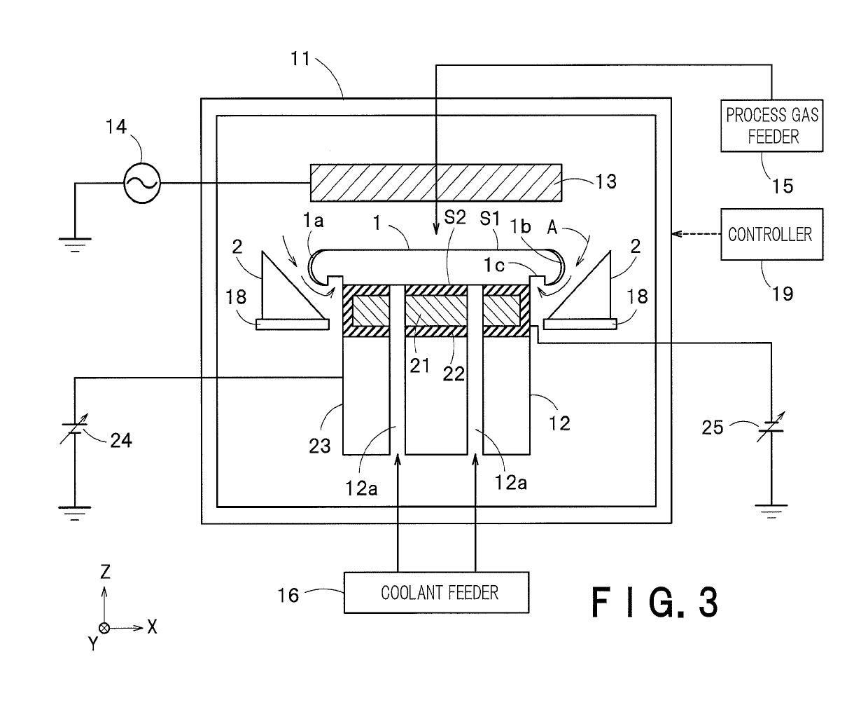

FIG. 3 is a cross-sectional view illustrating a structure of a plasma processing apparatus in the comparative example of the first embodiment.

In the present comparative example, as indicated by the arrow A, the radicals in the plasma reach the space between the bevel 1a of the wafer 1 and the dummy ring 2 (FIG. 3). However, no He gas is fed to the space between the bevel 1a of the wafer 1 and the dummy ring 2 because the ESC 12 in the present comparative example lacks the second flow paths 12b and the gas holes P1.

Consequently, there are problems that the radicals enter the space to form a deposition film 1b on the bevel 1a of the wafer 1 and form a concave portion 1c, on the rear face S2 of the wafer 1 by etching. For example, the former phenomenon is caused by the radicals for a deposition process during dry etching, and the latter phenomenon is caused by the radicals for dry etching. When the concave portion 1c is deep, a hole is formed in a protection film due to wet etching that is performed after the plasma etching. Accordingly, a film to be protected is etched during the wet etching.

On the other hand, in the present embodiment, the radicals in the plasma reach the space between the bevel 1a of the wafer 1 and the dummy ring 2, as indicated by the arrow A (FIG. 1).

Furthermore, the He gas is fed to the space between the bevel 1a of the wafer 1 and the dummy ring 2, as indicated by the arrow B, because the ESC 12 in the present embodiment includes the second flow paths 12b and the gas holes P1.

The plasma processing apparatus in the present embodiment generates the plasma in the process chamber 11 to process the wafer 1 with the plasma while feeding the He gas to the above-mentioned space to fill the space with the He gas. For this reason, the He gas can block the radicals from entering the space. Therefore, according to the present embodiment, the bevel 1a and the rear face S2 of the wafer 1 can be protected from the plasma, and formations of the deposition film 1b and the concave portion 1c can be suppressed.

Details of the plasma processing apparatus in the first embodiment will be described with reference to FIG. 1.

In the present embodiment, an inert gas such as the He gas is used as a block gas for blocking the radicals. The block gas may be a gas other than the inert gas. However, using the inert gas as the block gas has an advantage of preventing the reaction between the block gas and the wafer 1. In the present embodiment, although the coolant is diverted for the block gas, the block gas does not need to cool other solids or fluids.

In the present embodiment, although the first flow paths 12a and the second flow paths 12b are separated from each other in the ESC 12, the first flow paths 12a and the second flow paths 12b may be branched from a common flow path. However, the first flow paths 12a and the second flow paths 12b separated from each other in the ESC 12 have an advantage that each second flow path 12a can be easily connected to a MFC 17.

When the flow rate of the He gas discharged from each gas hole P1 is too small, the He gas may fail to block the radicals effectively. In contrast, when the flow rate of the He gas discharged from each gas hole P1 is too large, the He gas may disturb processing of the wafer 1. According to the present embodiment, these problems can be prevented by controlling the flow rate of the He gas to an appropriate value by each MFC 17.

The second flow paths 12b and the gas holes P1 in the present embodiment can also be applied to a plasma processing apparatus other than the plasma etching apparatus. An example of such a plasma processing apparatus includes a plasma chemical vapor deposition (CVD) apparatus for forming a deposition film on the wafer 1 with the plasma.

As described above, the plasma processing apparatus in the present embodiment feeds the inert gas to the space between the bevel 1a of the wafer 1 and the dummy ring 2 by discharging the inert gas to the side of the rear face S2 of the wafer 1 from the gas holes P1 provided on the side face of the ESC 12. Therefore, according to the present embodiment, the rear face S2 of the wafer 1 can be protected from the plasma in the plasma processing of the front face S1 of the wafer 1.

### Second Embodiment

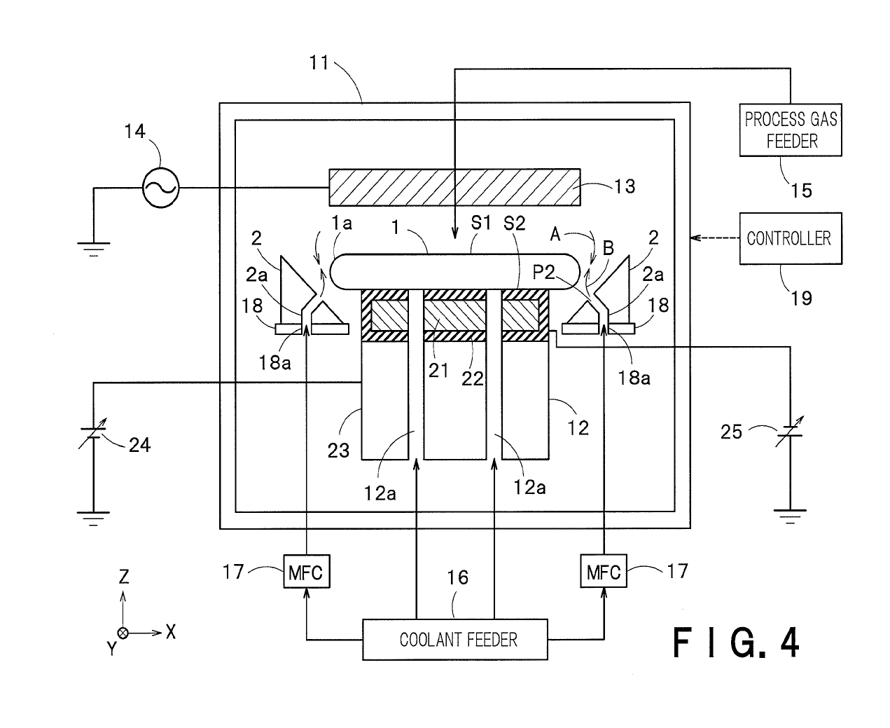

FIG. 4 is a cross-sectional view illustrating a structure of a plasma processing apparatus in a second embodiment.

In the first embodiment, the second flow paths 12b are provided in the ESC 12, and the gas holes P1 connected to the second flow paths 12b are provided on the side face of the ESC 12 (FIG. 1). In the second embodiment, second flow paths 18a are provided in the dummy ring holder 18, and second flow paths 2a connected to the second flow paths 18a are provided in the dummy ring 2, and gas holes P2 connected to the second flow paths 2a are provided on an inner circumferential face of the dummy ring 2 (FIG. 4). The second flow paths 2a extend from a bottom face of the dummy ring 2 to the inner circumferential face of the dummy ring 2.

The coolant feeder 16 in the present embodiment feeds the coolant to the wafer 1 through the first flow paths 12a in the ESC 12. The coolant in the present embodiment is an inert gas such as a rare gas, for example, a helium (He) gas. The coolant feeder 16 in the present embodiment further feeds the He gas to the second flow paths 18a and 2a that are provided in the dummy ring holder 18 and the dummy ring 2 and are connected to the gas holes P2. The He gas is discharged from the gas holes P2 to the side of the rear face S2 of the wafer 1. As a result, as illustrated by the arrow B, the He gas is fed to the space between the bevel 1a of the wafer 1 and the dummy ring 2 so that the space is filled with the He gas.

The second flow paths 18a and 2a may be arranged at equal intervals as similar to the second flow paths 12b in FIG. 2, or may be arranged at non-equal intervals.

As described above, the plasma processing apparatus in the present embodiment feeds the inert gas to the space between the bevel 1a of the wafer 1 and the dummy ring 2 by discharging the inert gas from the gas holes P2 provided on the side face of the dummy ring 2 to the side of the rear face S2 of the wafer 1. Therefore, according to the present embodiment, the rear face S2 of the wafer 1 can be protected from the plasma in the plasma processing of the front face S1 of the wafer 1.

In general, the dummy ring 2 is an expendable, and therefore the dummy ring 2 in the plasma processing apparatus is replaceable with another dummy ring 2. According to the second embodiment, when the existing dummy ring 2 is to be replaced, the existing dummy ring 2 can be replaced with another dummy ring 2 that has the gas holes P2 provided at more preferable positions. On the other hand, according to the first embodiment, a burden of forming the gas holes P2 in each dummy ring 2 can be omitted.

### Third Embodiment

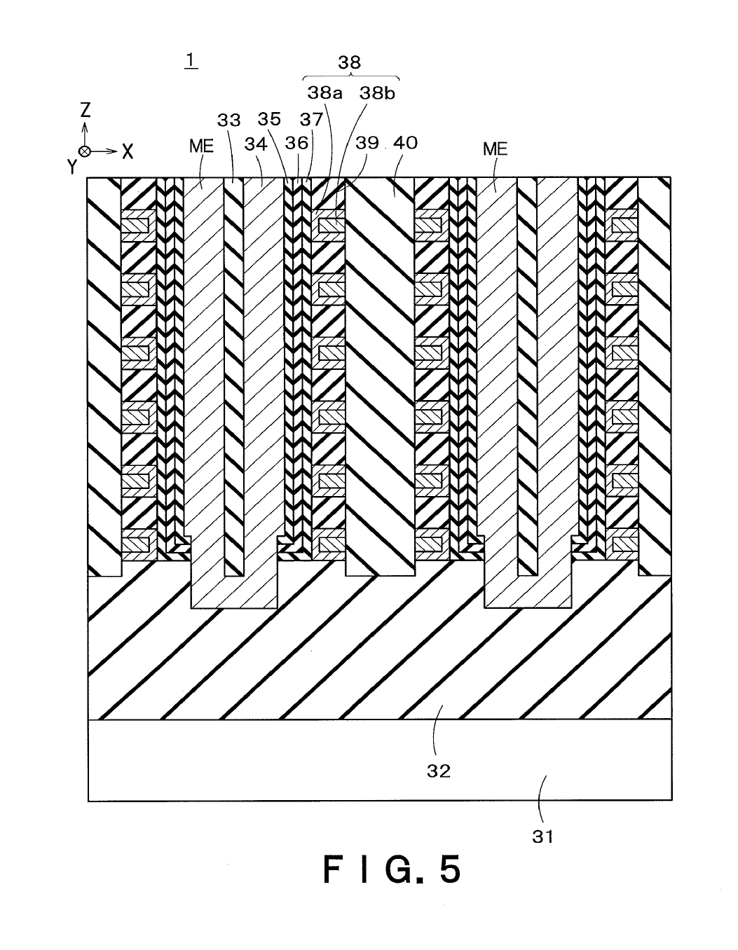

FIG. 5 is a cross-sectional view illustrating a structure of a semiconductor device in a third embodiment. The semiconductor device in FIG. 5 includes a three-dimensional flash memory, and is manufactured from the wafer 1 in the first or second embodiment. FIG. 5 shows two memory elements ME in the flash memory.

The semiconductor device in FIG. 5 includes a semiconductor substrate 31 and an inter layer dielectric 32. For each memory element ME, the semiconductor device in FIG. 5 further includes a first memory insulator 33, a semiconductor layer 34, a second memory insulator 35, a charge storing layer 36, a third memory insulator 37, plural interconnects 38 and plural insulators 39. The semiconductor device in FIG. 5 further includes an inter layer dielectrics 40.

An example of the semiconductor substrate 31 is a silicon substrate. The inter layer dielectric 32 is formed on the semiconductor substrate 31. An example of the inter layer dielectric 32 is a silicon oxide film. The inter layer dielectric 32 may be formed directly on the semiconductor substrate 31, or may be formed on the semiconductor substrate 31 via another layer.

The first memory insulator 33 is formed on the inter layer dielectric 32 via the semiconductor layer 34 and has a columnar shape extending in the Z direction. An example of the first memory insulator 33 is a silicon oxide film.

The semiconductor layer 34 is formed on the inter layer dielectric 32 such that the semiconductor layer 34 is in contact with side and lower faces of the first memory insulator 33. The semiconductor layer 34 has a tube shape extending in the Z direction around the first memory insulator 33, excluding a portion provided in the vicinity of the lower face of the first memory insulator 33. An example of the semiconductor layer 34 is a monocrystalline silicon layer.

The second memory insulator 35 is formed on the inter layer dielectric 32 such that the second memory insulator 35 is in contact with a side face of the semiconductor layer 34. The second memory insulator 35 has a tube shape extending in the Z direction around the semiconductor layer 34. An example of the second memory insulator 35 is a silicon oxide film.

The charge storing layer 36 is formed on the inter layer dielectric 32 such that the charge storing layer 36 is in contact with a side face of the second memory insulator 35. The charge storing layer 36 has a tube shape extending in the Z direction around the second memory insulator 35. Examples of the charge storing layer 36 are a silicon nitride film, a polycrystalline silicon layer and the like.

The third memory insulator 37 is formed on the inter layer dielectric 32 such that the third memory insulator 37 is in contact with a side face of the charge storing layer 36. The third memory insulator 37 has a tube shape extending in the Z direction around the charge storing layer 36. An example of the third memory insulator 37 is a silicon oxynitride film.

The plural interconnects 38 and the plural insulators 39 are alternately stacked on the inter layer dielectric 32 such that the interconnects 38 and the insulators 39 are in contact with a side face of the third memory insulator 37. The interconnects 38 and the insulators 39 have ring shapes surrounding the third memory insulator 37. Each interconnect 38 includes a barrier metal layer 38a and an interconnect material layer 38b. Examples of the barrier metal layer 38a are a titanium nitride (TiN) layer, a tantalum nitride (TaN) layer, a tungsten nitride (WN) layer and the like. Examples of the interconnect material layer 38b are a nickel (Ni) layer, a cobalt (Co) layer, a tungsten (W) layer and the like. An example of the insulators 39 is silicon oxide films.

The inter layer dielectric 40 is formed around the memory element ME on the inter layer dielectric 32. An example of the inter layer dielectric 40 is a silicon oxide film.

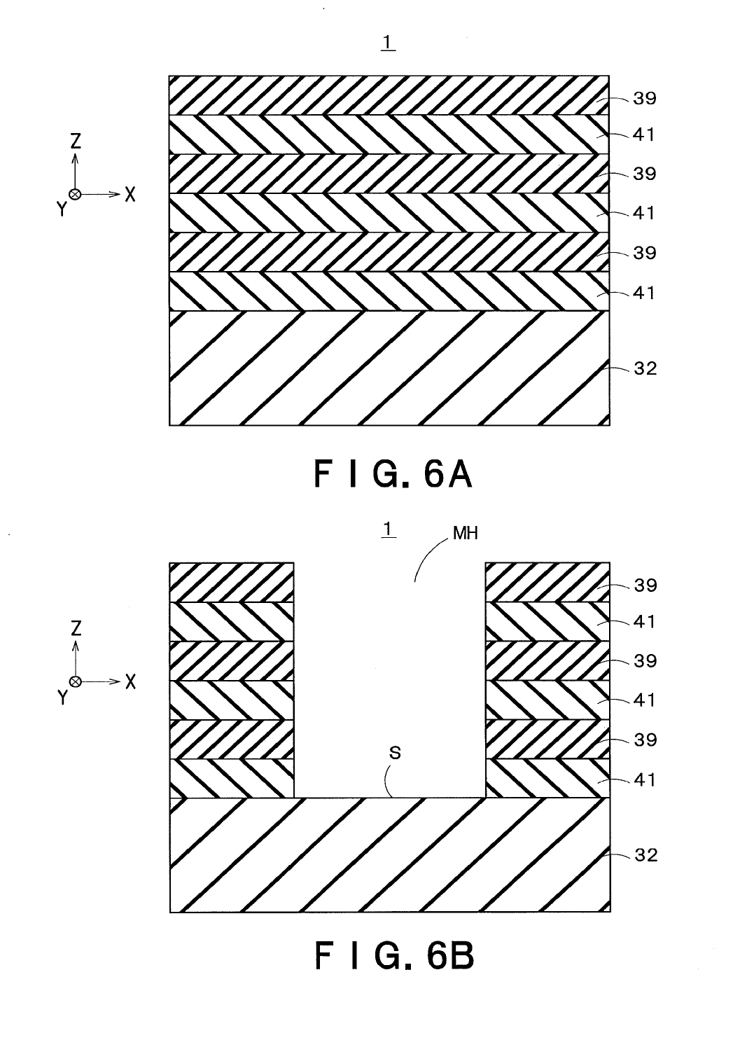

FIG. 6A to 10B are cross-sectional views illustrating a method of manufacturing the semiconductor device in the third embodiment.

The inter layer dielectric 32 is formed on the semiconductor substrate 31 (not illustrated), and plural sacrificial films 41 and the plural insulators 39 are alternately formed on the inter layer dielectric 32 (FIG. 6A). An example of the sacrificial films 41 is silicon nitride films. An example of the insulators 39 is silicon oxide films.

A memory hole MH that penetrates the sacrificial films 41 and the insulators 39 and reaches the inter layer dielectric 32 is formed by lithography and plasma etching (FIG. 6B). Reference character “S” denotes the bottom face of the memory hole MH. This plasma etching is performed in the plasma processing apparatus in the first or second embodiment. Specifically, the wafer 1 is transferred into the process chamber 11 after the step of FIG. 6A, and the wafer 1 is then processed with the plasma while the space between the bevel 1a of the wafer 1 and the dummy ring 2 is filled with the He gas. It is noted that plural memory holes MH are formed in this step but one of the memory holes MH is illustrated in FIG. 6B.

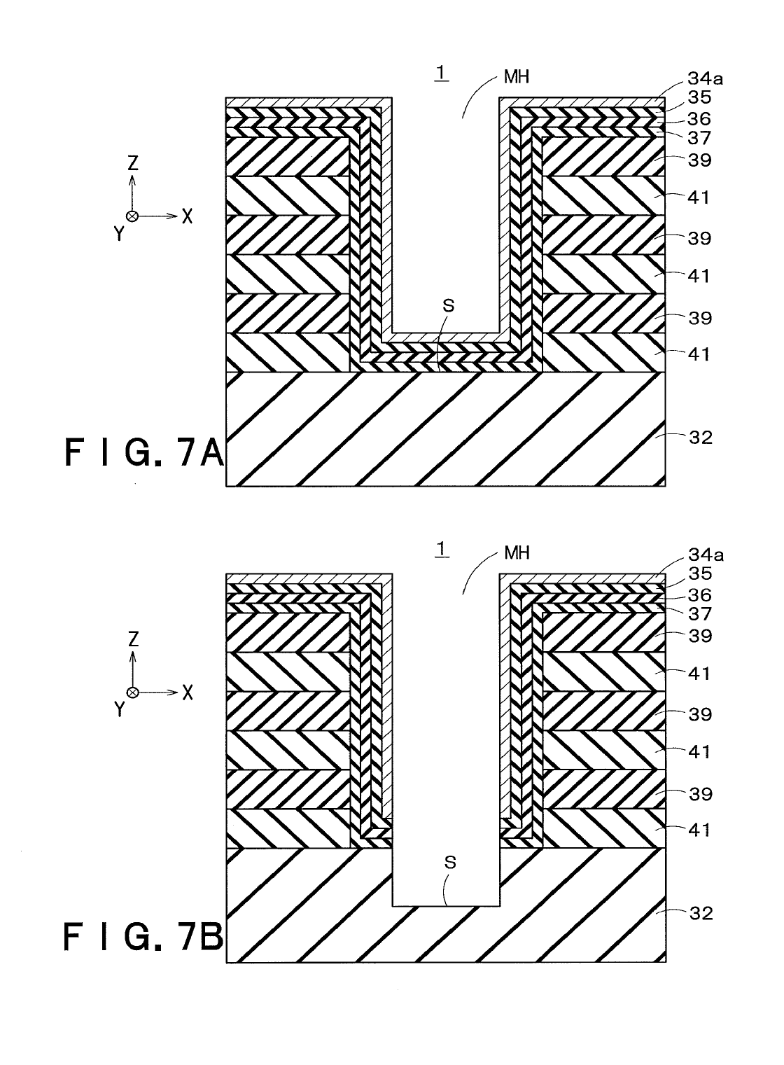

The third memory insulator 37, the charge storing layer 36, the second memory insulator 35, and a first layer 34a of the semiconductor layer 34 are sequentially formed over the entire surface of the semiconductor substrate 31 (FIG. 7A). As a result, the third memory insulator 37, the charge storing layer 36, the second memory insulator 35 and the first layer 34a are sequentially formed on the side face and the bottom face S of the memory hole MH. An example of the first layer 34a is an amorphous silicon layer.

The third memory insulator 37, the charge storing layer 36, the second memory insulator 35 and the first layer 34a are removed from the bottom face S of the memory hole MH by lithography and etching (FIG. 7B). As a result, the bottom face S of the memory hole MH is exposed again. Furthermore, since the inter layer dielectric 32 is also etched, the bottom face S of the memory hole MH is made lower than the uppermost face of the inter layer dielectric 32. This etching may be performed in the plasma processing apparatus in the first or second embodiment.

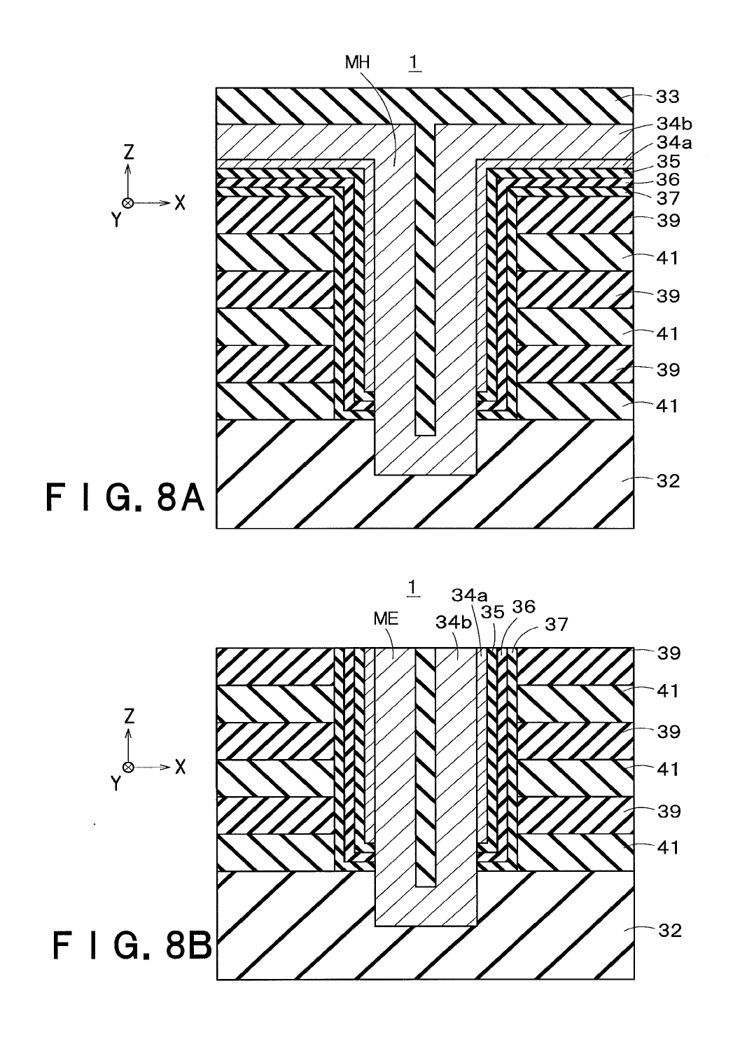

A second layer 34b of the semiconductor layer 34 and the first memory insulator 33 are sequentially formed over the entire surface of the semiconductor substrate 31 (FIG. 8A). As a result, the second layer 34b is formed on the bottom face S of the memory hole MH. The second layer 34b is formed on the side face of the memory hole MH via the third memory insulator 37, the charge storing layer 36, the second memory insulator 35 and the first layer 34a. Furthermore, the first memory insulator 33 completely embeds the memory hole MH. An example of the second layer 34b is an amorphous silicon layer.

The surfaces of the first memory insulator 33 and the semiconductor layer 34 are then planarized by chemical mechanical polishing (CMP) (FIG. 8B). Subsequently, the semiconductor substrate 31 is annealed so that the semiconductor layer 34 is crystallized to be a monocrystalline silicon layer.

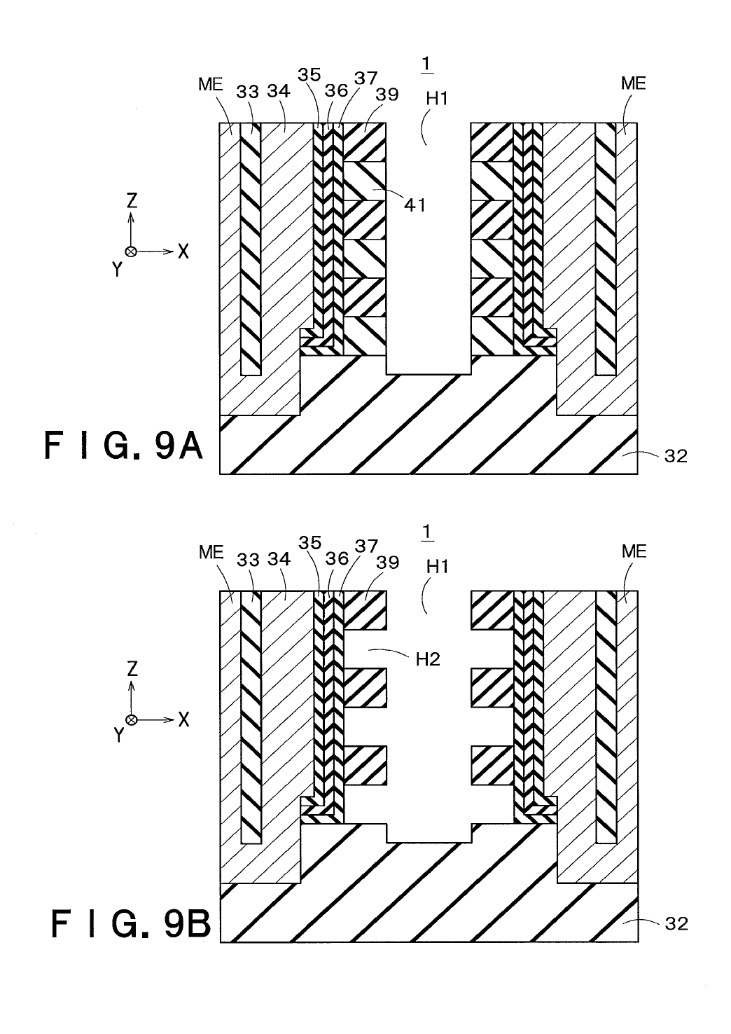

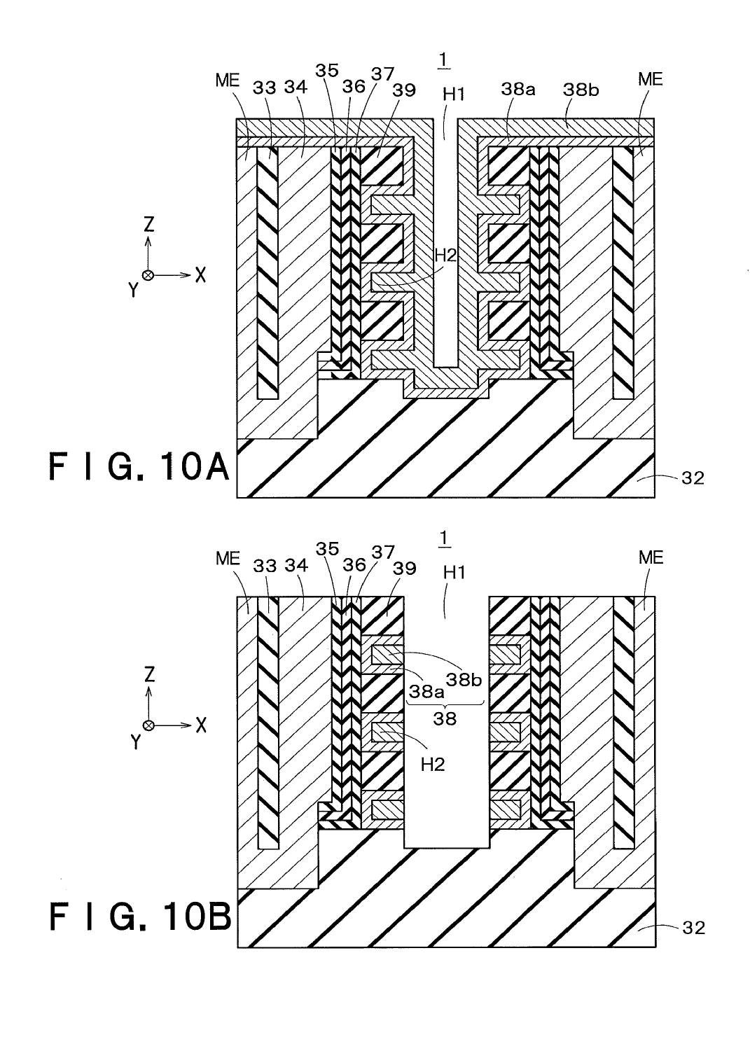

FIGS. 6A to 8B each illustrates a cross section of one memory element ME whereas FIGS. 9A to 10B each illustrates cross sections of two memory elements ME.

An opening H1 that penetrates the sacrificial films 41 and the insulators 39 and reaches the inter layer dielectric 32 is then formed by lithography and plasma etching (FIG. 9A). Since the inter layer dielectric 32 is also etched in this step, the bottom face of the opening H1 is made lower than the uppermost face of the inter layer dielectric 32. This plasma etching is performed in the plasma processing apparatus in the first or second embodiment. Specifically, the wafer 1 is transferred into the process chamber 11 after the step of FIG. 8B, and the wafer 1 is then processed with the plasma while the space between the bevel 1a of the wafer 1 and the dummy ring 2 is filled with the He gas. The opening H1 is formed in a region for forming the inter layer dielectric 40 in FIG. 5.

The sacrificial films 41 are removed by selective etching while the insulators 39 are left (FIG. 9B). As a result, concave portions H2 are formed between the insulators 39. The concave portions H2 are also formed between the lowest insulator 39 and the inter layer dielectric 32. The side face of the third memory insulator 37 is exposed from the concave portions H2 by this etching. This etching may be performed in the plasma processing apparatus in the first or second embodiment.

The barrier metal layer 38a and the interconnect material layer 38b are sequentially formed over the entire surface of the semiconductor substrate 31 (FIG. 10A). As a result, the barrier metal layer 38a is formed over upper, lower and side faces of the concave portions H2, and the interconnect material layer 38b is formed in the concave portions H2 via the barrier metal layer 38a. This step is performed such that the barrier metal layer 38a and the interconnect material layer 38b completely embed the concave portions H2.

The barrier metal layer 38a and the interconnect material layer 38b are etched by wet etching (FIG. 10B). As a result, the barrier metal layer 38a and the interconnect material layer 38b provided outside the concave portions H2 are removed, and the interconnects 38 including the barrier metal layer 38a and the interconnect material layer 38b is formed in the respective concave portions H2. According to the present embodiment, etching of a film to be protected can be avoided during this wet etching.

Thereafter, the inter layer dielectric 40 is formed in the opening H1. Furthermore, various inter layer dielectrics, interconnect layers, plug layers and the like are formed on the semiconductor substrate 31. In this way, the semiconductor device in the present embodiment is manufactured.

As described above, the semiconductor device of the present embodiment is manufactured from the wafer 1 by performing the plasma processing of the wafer 1 with the plasma processing apparatus in the first or the second embodiment. Therefore, according to the present embodiment, the rear face S2 of the wafer 1 can be protected from the plasma during the plasma processing of the front face S1 of the wafer 1.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods and described herein may be made without departing from the spirit of the inventions. The accompanying claims and their equivalents are intended to cover such forms or modifications as would fall within the scope and spirit of the inventions.

1. A plasma processing apparatus comprising:
an electrostatic chuck configured to hold a substrate;
a surrounding member holder configured to hold a surrounding member that surrounds an edge portion of the substrate;
a plasma feeder configured to feed plasma for processing the substrate to a side of a first face of the substrate; and
a gas feeder configured to feed a gas to a space between the edge portion of the substrate and the surrounding member by discharging the gas to a side of a second face of the substrate from a gas hole provided on a side face of the electrostatic chuck or a gas hole provided in the surrounding member.

2. The apparatus of claim 1, wherein the gas is an inert gas.

3. The apparatus of claim 1, further comprising a flow rate controller configured to control a flow rate of the gas discharged from the gas hole.

4. The apparatus of claim 1, wherein the gas feeder comprises a coolant feeder configured to feed a coolant for cooling the substrate to the substrate, and discharges the coolant as the gas from the gas hole.

5. The apparatus of claim 4, wherein the electrostatic chuck comprises a first flow path for feeding the coolant to the substrate, and a second flow path for discharging the coolant as the gas from the gas hole.

6. The apparatus of claim 5, wherein the electrostatic chuck comprises a plurality of holes as the gas hole, and comprises a plurality of paths connected to the plurality of holes as the second flow path.

7. The apparatus of claim 6, wherein the plurality of paths extend radially in vicinities of the plurality of holes.

8. The apparatus of claim 4, wherein
the electrostatic chuck comprises a first flow path for feeding the coolant to the substrate, and
the surrounding member comprises a second flow path for feeding the coolant as the gas from the gas hole.

9. The apparatus of claim 1, wherein the plasma feeder comprises a process gas feeder configured to feed a process gas for generating the plasma, a first electrode provided outside the electrostatic chuck, and a second electrode provided in the electrostatic chuck, and generates the plasma from the process gas by the first and second electrodes.

10. The apparatus of claim 1, wherein the plasma feeder feeds the plasma for etching the substrate.

11. A method of manufacturing a semiconductor device, comprising:
holding a substrate by an electrostatic chuck;
surrounding an edge portion of the substrate by a surrounding member;
feeding plasma for processing the substrate to a side of a first face of the substrate; and
feeding a gas to a space between the edge portion of the substrate and the surrounding member by discharging the gas to a side of a second face of the substrate from a gas hole provided on a side face of the electrostatic chuck or a gas hole provided in the surrounding member.

12. The method of claim 11, wherein the gas is an inert gas.

13. The method of claim 11, further comprising controlling, by a flow rate controller, a flow rate of the gas discharged from the gas hole.

14. The method of claim 11, further comprising feeding a coolant for cooling the substrate to the substrate, and discharging the coolant as the gas from the gas hole.

15. The method of claim 14, wherein the electrostatic chuck comprises a first flow path for feeding the coolant to the substrate, and a second flow path for discharging the coolant as the gas from the gas hole.

16. The method of claim 15, wherein the electrostatic chuck comprises a plurality of holes as the gas hole, and comprises a plurality of paths connected to the plurality of holes as the second flow path.

17. The method of claim 16, wherein the plurality of paths extend radially in vicinities of the plurality of holes.

18. The method of claim 14, wherein
the electrostatic chuck comprises a first flow path for feeding the coolant to the substrate, and
the surrounding member comprises a second flow path for feeding the coolant as the gas from the gas hole.

19. The method of claim 11, further comprising:
feeding a process gas for generating the plasma; and
generating the plasma from the process gas by a first electrode provided outside the electrostatic chuck and a second electrode provided in the electrostatic chuck.

20. The method of claim 11, further comprising etching the substrate with the plasma.
